(19) United States
(12) Patent Application Publication
(10) Pub. No.: US 2007/0295384 A1
(43) Pub. Date: Dec. 27, 2007

(54) Light converging-type solar photovoltaic apparatus

(75) Inventors: Hisafumi Uozumi, Nagoya-shi (JP); Kenji Araki, Nagoya-shi (JP); Taizo Yano, Nagoya-shi (JP)

Correspondence Address: BACON & THOMAS, PLLC, 625 SLATERS LANE, FOURTH FLOOR, ALEXANDRIA, VA, 22314, US

(73) Assignee: DAIDO TOKUSHUKO KABUSHIKI KAISHA, Nagoya-shi (JP)

(21) Appl. No.: 11/812,158

(22) Filed: Jun. 15, 2007

(30) Foreign Application Priority Data
Jun. 21, 2006 (JP) 2006-170978

(51) Int. Cl. H01L 31/048

(52) U.S. Cl. 136/246

(57) ABSTRACT

The present invention provides a light converging-type solar photovoltaic apparatus having: a case having: a bottom member; a peripheral member; and an upper member so as to form a space in the case, the case inclining so as to face the upper member to the sun; a plurality of Fresnel lenses provided at the upper member, the Fresnel lenses converging sun light; a plurality of solar battery cells provided in the case, the solar battery cells each receiving each sun light converged by the Fresnel lenses to generate electric power, the peripheral member having surfaces opposed to each other, the opposed surfaces each having at least one opening portion, and a vent valve provided at each opening portion, the vent valve having a mesh interrupting ventilation upon a water film being formed on the mesh.

### FIELD OF THE INVENTION

The present invention relates to a light converging-type solar photovoltaic apparatus in which sunlight is converged on a solar battery cell via a Fresnel lens to generate electric power.

### BACKGROUND OF THE INVENTION

A light converging-type solar photovoltaic apparatus of a related art includes a light converging plate on which a plurality of Fresnel lenses each for converging sunlight are juxtaposed and a supporting plate disposed in parallel to the light converging plate with a predetermined distance therebetween. A plurality of solar battery cells, which receive the sunlight converged by the plurality of Fresnel lenses, respectively, are provided on the supporting plate.

The sunlight is converged by the Fresnel lenses and irradiated on the solar battery cells, respectively, whereby sunlight energy is converted into electric power to generate electric power (see a reference 1, for example).

[Reference 1] JP-A-2005-142373

The light converging-type solar photovoltaic apparatus of the related art is provided with through holes at plural positions of the supporting plate so that sunlight is irradiated also on shade portions of the generator to greening the shade portions.

Thus, there arises a problem that dust or insects enter into a case via the through holes to pollute the Fresnel lenses and the solar battery cells thereby to degrade the electric power generation efficiency.

Further, at the time of raining, rainwater flows within the case via the through holes to wet the solar battery cells and electric parts such as wirings within the case to beak down the generator.

Thus, in the company of the applicant, in order to solve the aforesaid problems, an enclosure is provided so that dust or insects do not enter into the case via the through holes.

However, in this case, although dust and insects hardly enter into the case, water hardly vaporizes and flows out of the case when a small amount of the water enters into the case.

Thus, dew drops appear in the grooves of the Fresnel lenses due to the change of whether, the change of temperature difference between the open air and the inside of the case, etc.

Due to the dew drops, there arises a problem that water collected within the grooves degrades the light converging ability of the lenses to remarkably degrade the electric-power generation efficiency.

Further, since the Fresnel lenses scarcely absorb sunlight and so are hardly warmed by sunlight, there arises a problem that water collected in the grooves of the lenses do not disappear in a short time and remains for a long time even if the temperature within the case increases by sunlight, thereby remarkably obstructing the electric-power generation.

### SUMMARY OF THE INVENTION

An object of the invention is to provide a light converging-type solar photovoltaic apparatus which can generate electric power efficiently even when dew drops appear in the grooves of Fresnel lenses.

Another object of the invention is to provide a light converging-type solar photovoltaic apparatus which, at the time of raining, can prevent unnecessary water from entering into a case thereby to prevent the portions within the case from being wet.

Other objects and advantages will be clear easily from the drawings and the following expressions relating to the drawings.

A light converging-type solar photovoltaic apparatus 6 of the present invention comprises: a case 21 comprising: a bottom member 22; a peripheral member 23, 24, 25, 26; and an upper member 27 so as to form a space 28 in the case, the case 21 inclining so as to face the upper member 27 to the sun; a plurality of Fresnel lenses 45 provided at the upper member 27, the Fresnel lenses 45 converging sun light; a plurality of solar battery cells 37 provided in the case 21, the solar battery cells each receiving each sun light converged by the Fresnel lenses 45 to generate electric power, the peripheral member 23, 24, 25, 26 has surfaces opposed to each other, the opposed surfaces each has at least one opening portion 50, and a vent valve 51 is provided at each opening portion 50, the vent valve 51 comprises a mesh interrupting ventilation upon a water film is formed on the mesh.

Preferably, in the above light converging-type solar photovoltaic apparatus 6, the opposed surfaces each have at least two opening portions 50, 50, and one of the two opening portions is disposed at an upper portion close to the Fresnel lenses and the other is disposed at a lower portion close to the solar battery cells.

Further preferably, in the above light converging-type solar photovoltaic apparatus 6, the one of the two opening portions 50, 50 is disposed at a position where a distance between an upper end portion 50a of the opening portion and a lower edge 45b of the Fresnel lenses 45 is 30 mm or less, and the other is disposed at a position where a distance between a lower end portion 50b of the opening portion and the bottom member 22 of the case is 30 mm or less.

As described above, according to the invention, the Fresnel lenses converge the sunlight and irradiate on the solar battery cells to generate electric power. Further, even when dew drops appear in the grooves of the Fresnel lenses, the air flows from the lower end side of the case being inclined toward the upper end side thereof due to the opening portions provided at each of the opposing surfaces of the peripheral members of the case, so that the water collected in the grooves of the Fresnel lenses can be removed smoothly. Thus, the degraded time period of the light converging ability due to the water collected in the grooves can be made short, whereby the power generation time can be made longer and so the power generation efficiency can be improved.

Further, according to the invention, even if the opening portions are provided, the opening portion is closed so as to interrupt the ventilation by a water film formed on the vent valve provided at the opening portion. Thus, it is possible to attain such an effect in use that unnecessary water is prevented from entering into the case from the outside and so the portions within the case is prevented from being wet.

### BRIEF DESCRIPTION OF THE DRAWINGS

FIG. 1 is a perspective view for explaining a light converging-type solar photovoltaic mechanism.

FIG. 2 is a schematic perspective view for explaining a light converging-type solar photovoltaic module.

FIG. 3A is a diagram for explaining the ventilation within the case of the light converging-type solar photovoltaic module and shows a sectional view cut along a line III-III and a line III′-III′ in FIG. 2. FIG. 3B is a partially broken sectional diagram for explaining an example provided with a circulation fan in the light converging-type solar photovoltaic module. FIG. 3C is a partially broken sectional diagram for explaining an example provided with a water flashing plate and a circulation fan near the opening portion.

FIG. 4 is a sectional diagram for explaining the relation between a power generation element and the Fresnel lens in the power generation unit.

FIG. 5A is a diagram representing the relation between the peripheral member and the opening portion, in which the peripheral member is partially broken out. FIG. 5B is a sectional diagram cut along a line V-V in FIG. 5A in order to explain the relation between the peripheral member and the vent valve of the opening portion, in which the peripheral member is partially broken out.

FIG. 6 is a diagram showing a concrete example of the locations, the number and the sizes of the opening portions.

FIG. 7 is a partial perspective view for explaining an example of an opening portion different from that shown in FIGS. 1 to 6.

FIG. 8A is a partially broken sectional diagram showing an example a light converging-type solar photovoltaic mechanism Gh different from a light converging-type solar photovoltaic mechanism G FIG. 8B is a partially broken diagram at a position cut along a line VIIIa-VIIIa in FIG. 8A, and FIG. 8C is a partially broken diagram at a position cut along a line VIIIb-VIIIb in FIG. 8B.

The reference numerals used in the drawings denote the followings, respectively.
G light converging-type solar photovoltaic mechanism
1 base
2 pole
3 sunlight tracking device
6 light converging-type solar photovoltaic apparatus
6a light converging-type power generation module
7 upper surface (light receiving surface)
12 base
12a supporting arm
12b coupling arm
3 receiving table
21 case
22 bottom member
23 first peripheral member
24 second peripheral member
25 third peripheral member
26 fourth peripheral member
27 upper member
28 space
34 power generation unit
35 power generation element
36 seat plate
37 solar battery cell
8 pole
39 protection cover
39a through hole
45 Fresnel lens
45a upper end
4bb lower end
47 groove
50 opening portion
51 vent valve
53 adhesive
81 base
82 slidable receiving surface
83 notched portion
84 rail
85 sliding surface
86 receiving frame
87 bearing
88 rotation shaft on case side
90 azimuth angle adjusting device
91 inclination angle (elevational angle) adjusting device
92 sunlight tracking device
93 arrow

### DETAILED DESCRIPTION OF THE INVENTION

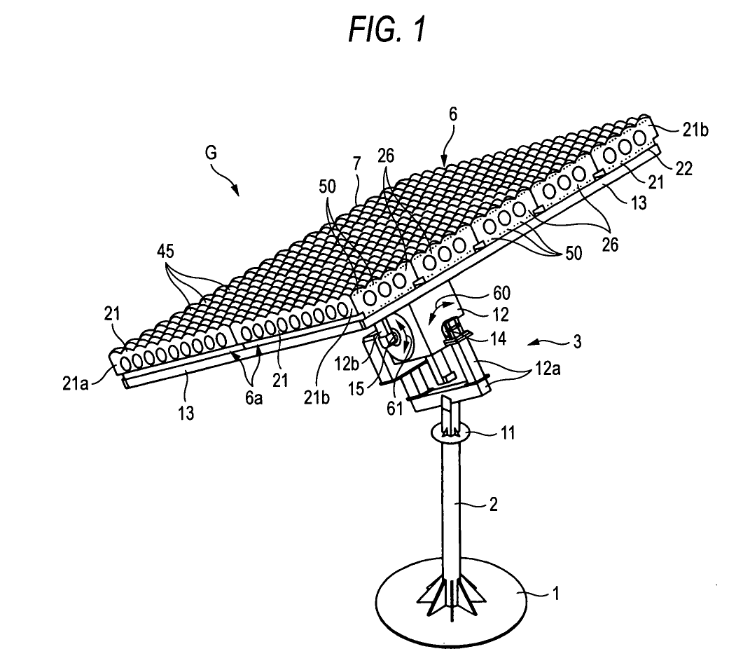

Embodiments of the invention will be explained with reference to FIGS. 1 to 7. In FIG. 1, G depicts a light converging-type solar photovoltaic mechanism having the same function as the usually known light converging-type solar photovoltaic mechanism. In the light converging-type solar photovoltaic mechanism G, 1 depicts a base for fixedly and stably setting the mechanism with respect to the ground or a structure, and 2 depicts a pole erected on the base.

3 depicts a device having the same function as a well-known sunlight tracking device for supporting the light converging-type solar photovoltaic apparatus 6 so as to incline freely with respect to the pole 2. The inclining configuration of this device is arranged as is well known in a manner that the upper surface 7 (also called a light receiving surface) of a light converging-type solar photovoltaic apparatus 6 is directed to the sun in a state that the base 1 is fixedly set and the light receiving surface 7 is sequentially inclined to a state with the highest light receiving efficiency according to the movement of the sun in accordance with a predetermined program.

In the sunlight tracking device 3, 12 depicts a base which has a driving source such as a motor for rotating rotation shafts 14, 15. 12a depicts a supporting arm which lower portion 11 is fixed to the head portion of the pole 2. The upper portion of the supporting arm is coupled to the rotation shaft 14 so that the base 12 freely rotates in an arrow direction 60 with respect to the supporting arm 12a.

12b depicts a coupling arm which upper portion is fixed to a receiving table 13. The lower portion of the coupling arm 12b is coupled to the rotation shaft 15 so that the coupling arm freely rotates in an arrow direction 61 with respect to the base 12. The receiving table 13 is a structure member for entirely supporting the light converging-type solar photovoltaic apparatus 6.

The movement of the sunlight tracking device 3 for tracking the sun with respect to the base 1 and the pole 2 each being in a standstill state is merely required to be a three-dimensional movement, and there are various types of supporting structures satisfying such a requirement.

Next, the explanation will be made as to the light converging-type solar photovoltaic apparatus 6.

As shown in FIG. 1, the light converging-type solar photovoltaic apparatus 6 is configured in a manner that a plurality of light converging-type power generation modules 6a are juxtaposed on the receiving table 13. The light converging-type power generation modules 6a are mutually coupled so as to be ventilated from one another via arbitrary ventilation paths.

Next, the explanation will be made as to a case 21 constituting the light converging-type power generation module 6a.

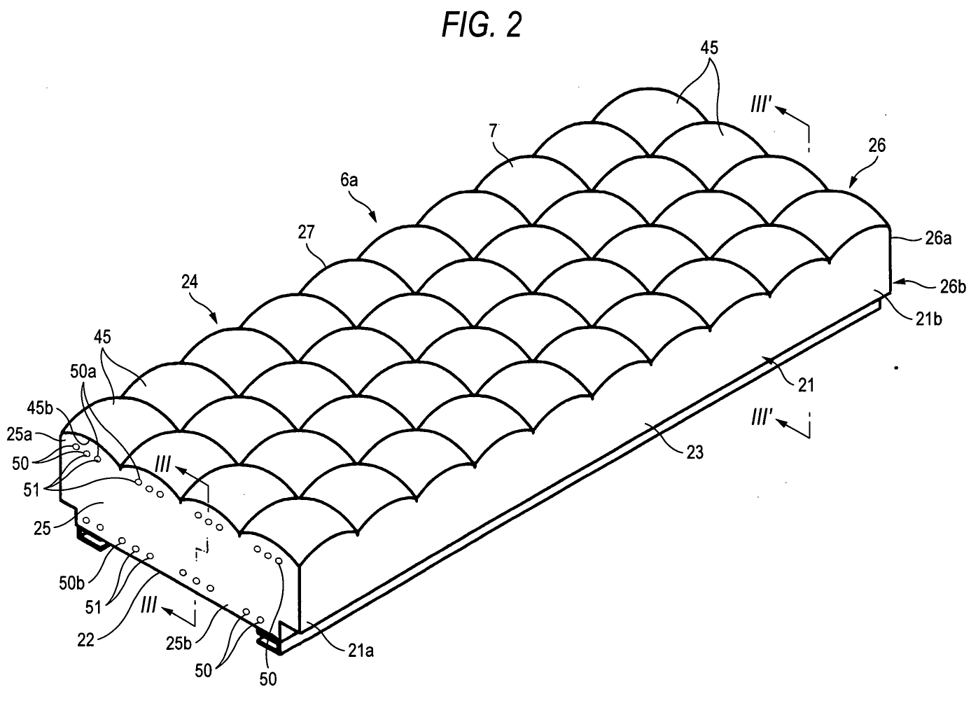

As shown in FIG. 2, the case 21 includes a bottom member 22, a first peripheral member 23, a second peripheral member 24, a third peripheral member 25, a fourth peripheral member 26 and an upper member 27 so as to cover the four peripheries (that is, upper, lower, left and right peripheries) and forms a space 28 therein. The space 28 within the case 21 is arranged so as to have a suitable sealing degree so that a large dust does not enter therein. The case is configured to have a drip-proof structure at the time of raining.

The bottom member 22 of the case 21 is a constructive member supported by the receiving table 13 of the sunlight tracking device 3 and is configured by a plate member.

Each of the first peripheral member 23, the second peripheral member 24, the third peripheral member 25 and the fourth peripheral member 26 is coupled to the bottom member 22 via a known means. These peripheral members are arranged so as to surround the space 28.

Each of the bottom member 22 and the first to fourth peripheral members 23, 24, 25, 26 is formed by a metal plate with good thermal conduction such as an iron plate, an aluminum plate.

The upper member 27 includes a frame 46 configured by an arbitrary constructive steel member and a plurality of Fresnel lenses 45.

The frame 46 is configured in a manner that steel members are disposed with an arbitrary interval therebetween so as to receive the Fresnel lenses 45 arranged orderly in all directions.

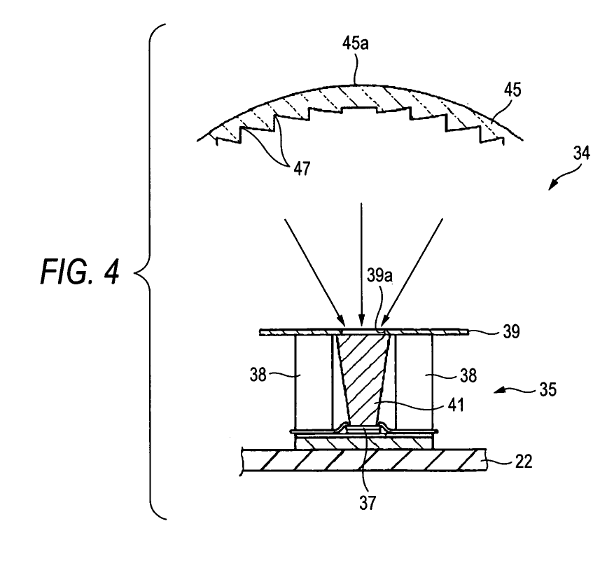

45 depicts a known Fresnel lens which is configured as well shown in FIG. 4 in a manner that the major surface thereof has a spherical shape and the rear surface thereof has a concavo-convex shape having annular steps. The Fresnel lens 45 is formed by resin material excellent in optical characteristics such as acrylic acid resin. 47 depicts grooves of the Fresnel lens 45.

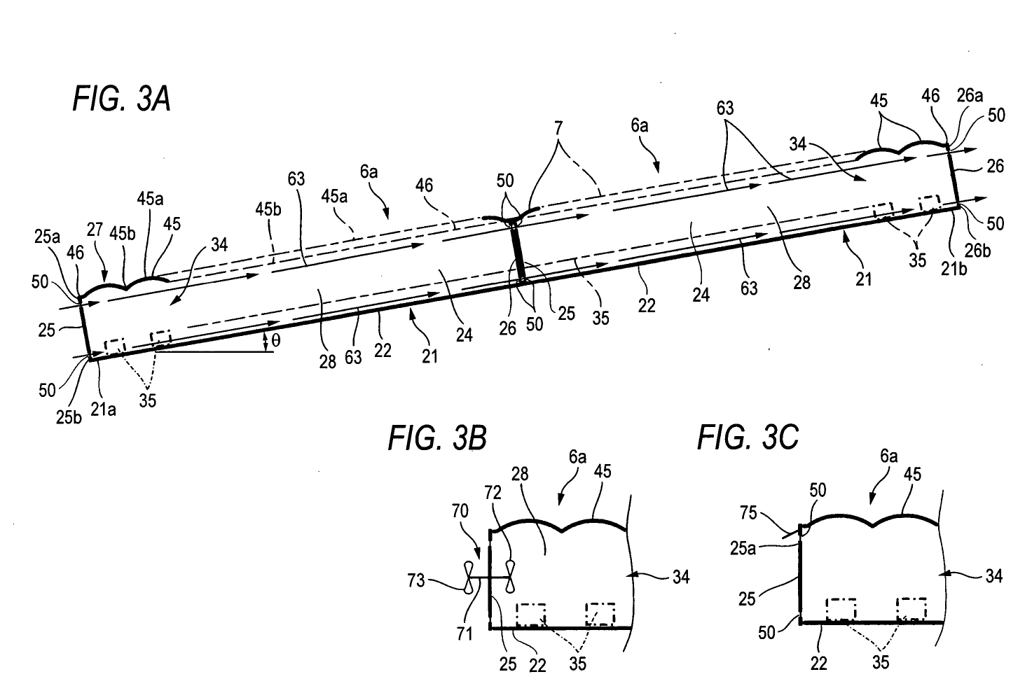

As shown in FIGS. 2 and 3, the Fresnel lenses 45 are arranged on and fixed to the frame 46 so as to be coupled mutually and orderly in all directions.

Although the configuration of the case 21 is explained as to a particular example, the case may be configured to have another known arbitrary closed structure.

Next, the explanation will be made as to a power generation unit 34, a plurality of which are disposed within the light converging-type power generation module 6a (see FIGS. 3 and 4). The power generation unit 34 includes the Fresnel lens 45 and a known power generation element 35. As shown in FIG. 4, the Fresnel lens 45 and the power generation element 35 are arranged to have such a positional relation that sunlight converged by the Fresnel lens 45 is focused on a solar battery cell 37.

As is well known, the power generation elements 35 are mutually coupled by wirings disposed on the member 22 so that the generation power of the respective elements is taken out of the light converging-type solar photovoltaic apparatus 6 via not-shown lead wires.

As shown in FIGS. 3 and 4, the power generation element 35 of the power generation unit 34 is fixedly disposed on the bottom member 22. In the power generation element 35, 37 depicts the cell, 39 depicts a protection cover for protecting the peripheral members from sunlight which is directly irradiated on the peripheral members when the sunlight tracking deviates, 38 a holding member for supporting the protection cover, 41 a homogenizer which equalizes the intensity of sunlight passed through the through hole of the protection cover 39 and introduces the sunlight thus equalized to the solar battery cell 37.

Next, the explanation will be made as to the opening portion 50. As to the disposing position of the opening portion 50 at the case 21, as estimated From FIGS. 1 to 3, at least one opening portion 50 is provided at each of the opposing surfaces of the peripheral members of the cases 21. In an example shown in FIGS. 1 to 3, the opening portion 50 is provided at each of the peripheral members 25, 26 located at the lower end side 21a and the upper end side 21b of the case inclined (by an angle θ) with respect to the horizontal line so that an air ventilation path is formed within the space 28 of the case. Further, the opening portion 50 may be provided at a portion of the first peripheral member 23 closer to the lower end side 21a and a portion of the second peripheral member 24 closer to the upper end side 21b opposing to the first peripheral member 23.

Next, in the peripheral member, at least two opening portions 50, 50 are disposed at each of opposing surfaces in a manner that the two opening portions 50, 50 at each surface are disposed at an upper portion close to the and a lower portion close to the solar battery cell.

In an example shown in FIGS. 1 to 3, in the third peripheral member 25, twelve opening portions 50 are disposed at the upper portion 25a close to the Fresnel lens 45 and ten opening portions are disposed at the lower portion 25b close to the bottom member 22. Further, in the fourth peripheral member 26 opposing to the third peripheral member 25, the opening portions are disposed in the similar manner as the third peripheral member 25.

The opening portion 50 at the upper portion 25a close to the Fresnel lens is preferably disposed so as to ventilate near the Fresnel lens 45 in a manner that a distance between the upper end opening portion 50a of the opening portion and the lower edge 45b of the Fresnel lens 45 is 30 mm or less. On the other hand, the opening portion 50 at the lower portion 25b close to the solar battery cell is preferably disposed in a manner that a distance between the lower end opening portion 50b of the opening portion and the bottom member 22 of the case is 30 mm or less.

The opening portion 50 may be formed to have an arbitrary size so that an air ventilation path is formed within the space 28 of the case 21 and the size may be set in view of the entire capacity of the case 21 and the configuration of a vent valve described later.

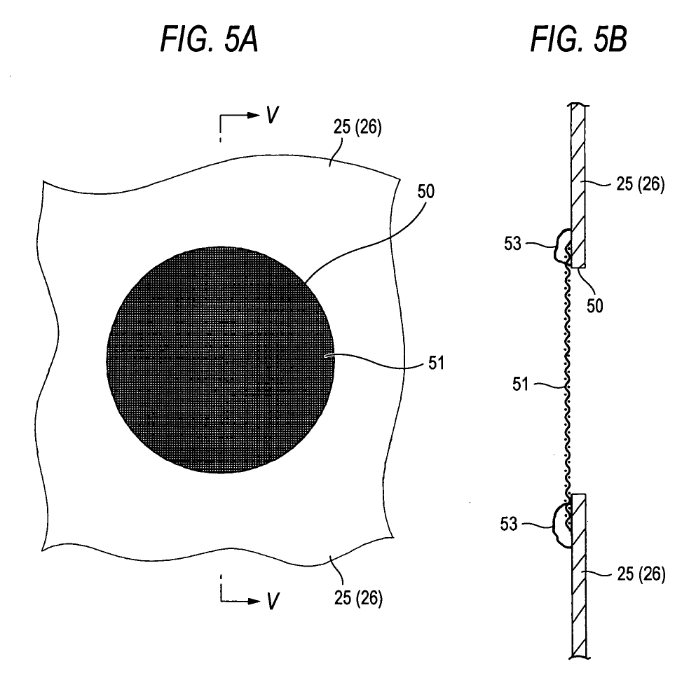

As shown in FIG. 5, 51 depicts a vent valve provided at the opening portion 50. The vent valve 51 is attached to the opening portion 50 as shown in FIG. 5B in a manner that the vent valve is attached to the rear sides (the inner side of the case 21) of the peripheral members 25, 26 in a close contact state by means of an adhesive 53. The adhesive 53 may be a silicon rubber of a sealing purpose.

The vent valve 51 is configured by a mesh so as to ventilate in a normal state and interrupt the ventilation when a water film is formed thereon. To be concrete, the water film is formed on the vent valve 51 by water adhered thereto due to a dew drop or rainwater contacted to the vent valve 51 at the time of raining. The mesh may be configured by a stainless wire so as to have 100 meshes or more, for example. Accordingly, even if the case 21 has the opening portions 50, a water film is formed on the vent valve 51 provided at the opening portion 50 thereby to close the valve so as to interpret the ventilation as described above, whereby unnecessary water is prevented from entering into the case 21 and so the portions within the case 21 is prevented from being wet.

Further, the mesh may be configured preferably, for example, in a manner that the material thereof is a stainless steel wire with a diameter of 60 μm, the number of the wires is 150 in a length of 25.4 mm, the thickness of the wire is 0.12 mm, and the rate of opening area is 42%.

The explanation will be made as to the using state of the thus configured generator.

First, the explanation will be made as to the air flow within the case of the light converging-type power generation module 6a, the state of the groove of the Fresnel lens 45 and the power generation state after the sunrise.

At the time of the sunrise, dew drops appear in the grooves 47 of the Fresnel lens 45 in general due to the temperature reduction during the night and the radiation cooling etc.

Then, when the sun rises gradually with the time lapse, sunlight is irradiated within the case and so the temperature within the case increases. As described above, since the case 21 is arranged in a manner that the surface of the upper member 27 is directed to the sun and the case is inclined as shown in FIG. 1 and FIG. 3A, the temperature difference appears between the lower end side 21a and the upper end side 21b of the case.

Thus, air flows within the case. That is, as shown by an arrow 63 in FIG. 3A, the open air flows into the case via the opening portions 50 at the lower end side 21a of the case, then the air flows toward the opening portions 50 at the upper end side 21b of the case and flows out of the case via the opening portions 50 at the upper end side 21b of the case.

To be more concrete, as shown by the arrow 63 in FIG. 3A, the air flowing into the case via the opening portion 50, disposed at the upper portion 25a close to the Fresnel lens 45 among the opening portions 50 at the lower end side 21a of the case, flows near the Fresnel lens 45. Thus, an air current appears near the Fresnel lens 45 to vaporize water collected in the grooves 47 thereby to remove the water in a short time.

On the other hand, the air flowing into the case via the opening portion 50 disposed at the lower portion 25b close to the bottom member 22 flows near the member 22. Thus, the dew drops generated on the bottom member 22 side are vaporized and the moisturized air is flows outside. Accordingly, the water near the bottom member 22 being evaporated is prevented from being directed to the light converging-type power generation module 6a.

When this state continues, the water collected in the grooves 47 of the Fresnel lenses 45 of the light converging-type power generation module 6a can be reduced quickly.

Thus, the sunlight irradiated toward the Fresnel lenses 45 is collected by the Fresnel lenses 45 in accordance with the design and directed toward the solar battery cells 37 to generate electric power as being expected.

A time period from a time point where sunlight is irradiated on the light converging-type power generation module 6a to a time point where the dew drops within the grooves 47 of all the Fresnel lenses 45 are removed completely varies depending on the capacity of the light converging-type power generation module 6a and the entire area of all the opening portions etc., but the time period is almost in a range from 20 minutes to one hour.

As described above, since the air flows from the lower end side 21a of the case to the upper end side 21b, the water collected in the grooves of the Fresnel lenses can be removed in a short time. Thus, the degraded time period of the light converging ability due to the water collected in the grooves can be made short, whereby the power generation time becomes longer and so the power generation efficiency is improved.

Next, the explanation will be made as to the states of the opening portion 50 and the vent valve 51 at the time of raining.

When a rain drop contacts the mesh of the vent valve 51, the water forms a water film on the surface of the plural meshes due to the surface tension. When a water drop of a predetermined amount contacts the vent valve 51, a water film is formed on the entire surface of the vent valve to close the opening portion 50 thereby to interrupt the ventilation of the opening portion 50. Thus, unnecessary water is prevented from entering into the case from the outside and so the portions within the case is prevented from being wet.

Next, the explanation will be made as to the states of the opening portion 50 and the vent valve 51 when the rain stops and the sun comes out.

When the sunlight irradiates on the case, the water film formed on the vent valve 51 evaporates and so the opening portion 50 is opened. Thus, like the aforesaid explanations as to the air flow within the case of the light converging-type power generation module 6a, the state of the grooves of the Fresnel lenses 45 and the power generation state after the sunrise, since the air flows from the lower end side 21a of the case to the upper end side 21b thereof, the bad effect due to the dew drops of the grooves 47 of the Fresnel lenses can be prevented.

### DESCRIPTION OF EXEMPLARY EMBODIMENTS

The present invention is now illustrated in greater detail with reference to several embodiments, but it should be understood that the present invention is not to be construed as being limited thereto.

### Embodiment 1

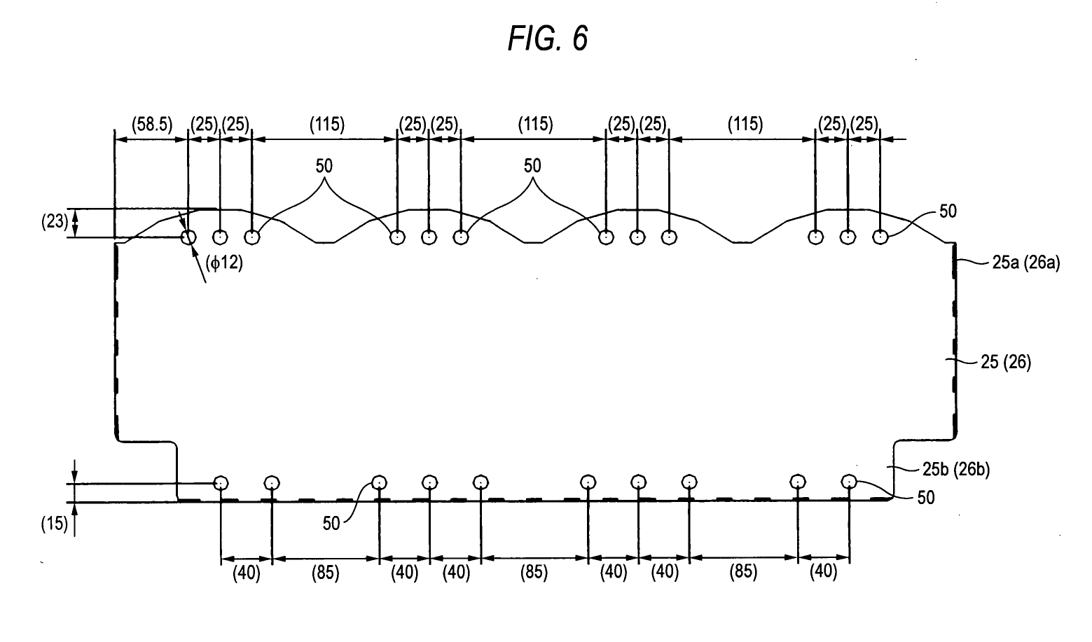

FIG. 6 shows a concrete example of the disposing positions, the number and the size of the opening portions 50. Numerals with parentheses shown in FIG. 6 represent the sizes (mm). For example, the size of the opening portion is 12 mm in its diameter.

### Embodiment 2

An example of the experimentation will be shown as to the relation between the entire area of the opening portions provided at the case of the light converging-type power generation module 6a and the condition of forming a dew drop.

(1) Method:

Twelve holes (opening portions) of f12 are provided at each of the upper and lower portions of each of the opposing peripheral members in the longitudinal direction of the power generation module (that is, a mini module (formed by 6 lenses each having a square size of 14 cm×14 cm)) with a capacity of 18,200 cm³, that is, 12×2×2=48 opening portions in total are provided. Each of the holes is covered by a stainless mesh with a rate of opening area of 42%. These holes are selectively covered by a paper tape to change the entire area of the opening portions, whereby the presence/non-presence of a dew drop is checked.

(2) Discrimination Condition of Dew Drop:

Water was soaked into a gauze of 5 cm square on the previous day and the gauze was placed within the module. On the next day, the module was taken out to the outdoor and irradiated with the sunlight. Thus, the water-soaked into the gauze evaporated and adhered to the lens to form dew drops thereon. It was checked how long did it take for the dew drops to disappear after being exposed to the sunlight.

(3) Results:

TABLE 1

| Number | | Total Area of | | |
|---|---|---|---|---|
| of holes | Number of holes | holes | V/S | Disappearing |
| (one side) | (both sides) | (cm²) | (cm) | time |
| 1 | 2 | 0.95 | 19,000 | 6 h 40 m |
| 2 | 4 | 1.9 | 9,600 | 1 h 10 m |
| 3 | 6 | 2.85 | 6,400 | 1 h |
| 4 | 8 | 3.8 | 4,800 | 50 m |
| 6 | 12 | 5.7 | 3,200 | 40 m |
| 8 | 16 | 7.6 | 1,200 | 20 m |
| 16 | 36 | 17.1 | 1,070 | 20 m |
| 20 | 40 | 19 | 960 | 20 m |

(4) Investigation:

In order to make the dew drops disappear within about one hour from the sunrise, V/S (the capacity of the module/entire area of the opening portions) is preferable to be smaller than about 10,000 cm. Since an amount of direct sunlight during one hour after the sunrise is only 5% of an entire amount of direct sunlight during one day, so that the reduction of an amount of power generation due to the dew drops can be negligible. Further, even if V/S is less than 1,000, the disappearing time of the dew drops did not change but there appeared bad influence that the surface rigidity degraded (see table 1).

(5) Conclusion:

Thus, the opening portion 50 is preferable to satisfy the condition of 1,000 cm<V/S<10,000 cm.

### Embodiment 3

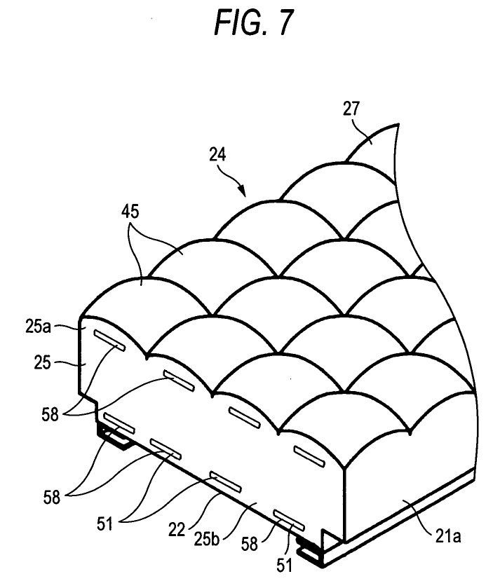

Next the explanation will be made with reference to FIG. 7 as to the generator which differs in the shape of the opening portions from that of FIGS. 1 to 6.

In FIG. 7, portions considered to be identical or similar in the functions, properties or features etc. to those of FIGS. 1 to 6 are referred to by the symbols common to those of FIGS. 1 to 6, with explanation thereof being omitted. (Further, in FIGS. 3B, 3C) used in the following explanation, portions considered to be identical in the similar manner are referred to by the symbols common to those of FIGS. 1 to 6, with explanation thereof being omitted.)

58 depicts opening portions each formed in an elongated shape. Like the opening portions 50 shown in FIGS. 1 to 6, the setting positions of the opening portions 58 in the case and the arrangement of the opening portions 58 in the peripheral members are set in a manner that air ventilation paths are formed in the space 28 within the case.

Although FIG. 7 shows an example where the shape of the opening portion is an elongated hole, the shape of the opening portion is not limited thereto and may be an arbitrary one which can form an air ventilation path in the space 28 within the case. That is, the shape of the opening portion may be a slit shape or a polygonal shape such as a triangle or a square.

### Embodiment 4

Next, the explanation will be made with reference to FIG. 3B as to an example which differs from the light converging-type power generation module 6a shown in FIGS. 1 to 6 in a point that a circulation fan is provided.

70 depicts a circulation fan for sending a soft wind so as to cause a turbulence within the space 28 of the case. 71 depicts a rotation shaft attached to the third peripheral member 25 of the case so as to be rotatable freely, and 72 depicts an inner fan fixed to the rotation shaft 71. 73 depicts a pinwheel fixed to the rotation shaft 71. As is well known, the pinwheel is arranged to be rotated by natural wind.

As shown in FIG. 3B, since the circulation fan is provided, the air within the case flows and so the ventilation is performed more efficiently.

### Embodiment 5

Next, the explanation will be made with reference to FIG. 3C as to an example which differs from the light converging-type power generation module 6a shown in FIGS. 1 to 6 in a point that a water flashing plate is provided near the opening portion.

75 depicts a water flashing plate for preventing rain water from entering into the case. The water flashing plate is disposed at the upper position of the outer periphery of the opening portion near the Fresnel lens 45 among the opening portions of the case 21.

According to this configuration, rain water is prevented from entering into the case.

### Embodiment 6

Next, the explanation will be made with reference to FIG. 3C as to an example which slightly differs from the light converging-type solar photovoltaic mechanism G shown in FIG. 1 in the configurations and the arrangements etc. of the elements of the base 1, the receiving table 3, the light converging-type solar photovoltaic apparatus 6, the case 21, and the power generation unit 34.

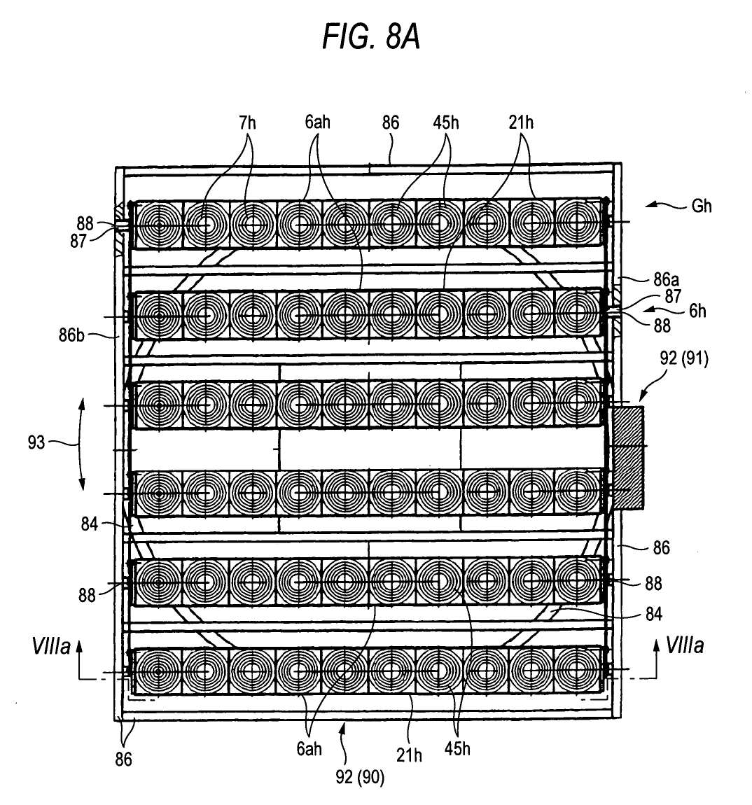

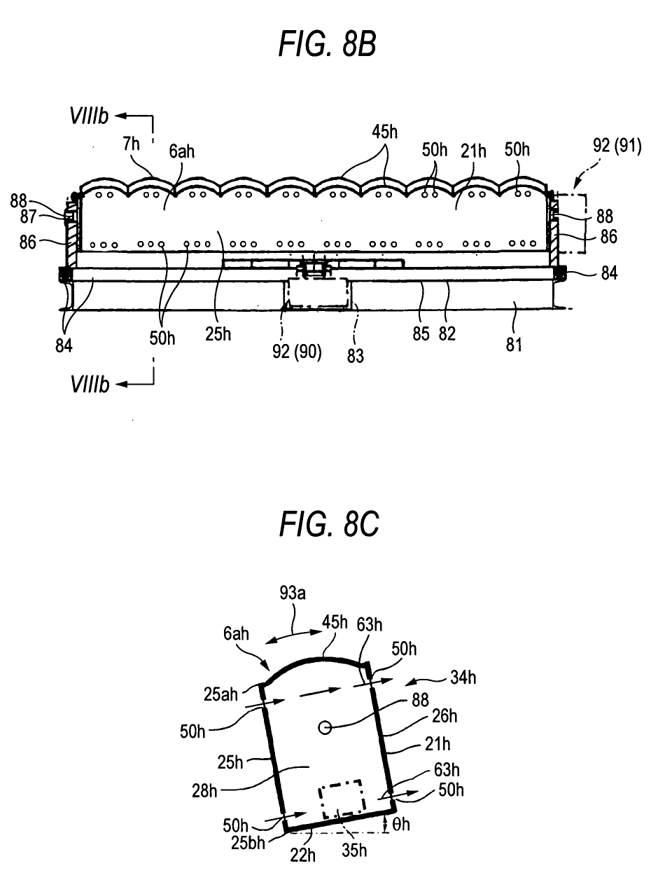

A light converging-type solar photovoltaic mechanism Gh shown in FIG. 8 is arranged to provide a relatively small light converging-type solar photovoltaic apparatus 6h. Unlike the case of FIG. 1, the case 21h of the light converging-type solar photovoltaic apparatus 6h is finely divided so as to provide the light converging-type solar photovoltaic apparatus 6h in which a plurality of the cases 21h are interlocked with a sunlight tracking device 92 to generate electric power efficiently.

Since FIG. 8 is partially same in the functions and the properties as the configurations of the light converging-type solar photovoltaic mechanism G shown in FIGS. 1 to 7, portions considered to be identical or similar in the functions, properties or features etc. to those of FIGS. 1 to 7 are referred to by attaching “h” to the symbols common to those of FIGS. 1 to 7, with explanation thereof being omitted.

In FIG. 8, 81 depicts a base corresponding to the base 1. This base is formed by hard material and is configured in an annular shape by a metal plate, for example The base serves to fix the generator to a structure. 82 depicts a slidable receiving surface of an annular shape for pivotally supporting a rail 84 so as to rotate freely, and 83 depicts a notched portion for disposing an azimuth angle adjusting device 90 among the mechanisms constituting a sunlight tracking device 92.

84 depicts the rail formed in an annular shape which is arranged to rotate reciprocally in an arrow 93 direction in a state that its sliding surface 85 is placed on the slidable receiving surface.

86 depicts a receiving frame, formed by hard material such as a metal plate, which is placed on the rail 84 and fixed thereto so as to rotate reciprocally in an arrow direction 93 in an integrated manner. The receiving frame is formed in a square form in its plan shape as shown in FIG. 8A.

The light converging-type solar photovoltaic apparatus 6h (which is configured by juxtaposing a plurality of the light converging-type power generation modules 6ah) is disposed on the opposing surfaces 86a, 86b of the receiving frame as shown in FIG. 8A, and a plurality of bearing members (through holes) 87 are juxtaposed so that each of the rotation shafts 88 of the light converging-type power generation modules 6h is rotatable.

The rotation shafts 88 protrusively erected at the both sides of the light converging-type power generation modules 6ah are interlocked mutually by arbitrary interlocking mechanisms. For example, each of the rotation shafts 88 is provided with an interlocking gear and these gears are interlocked by means of a rack or a worm gear. According to such a mechanism, a plurality of the light converging-type power generation modules 6ah are interlocked to act as the single light converging-type solar photovoltaic apparatus 6h.

Next, like the aforesaid case (like the case explained with reference to FIGS. 3 and 4), in the cases 21h, a plurality of power generation units 34h each configured by a Fresnel lens 45h provided at the upper portion and a known power generation element 35h provided at the lower portion are disposed in parallel as estimated from FIG. 8A.

90 and 91 respectively represent the presence of the azimuth angle adjusting device and an inclination angle (elevational angle) adjusting device which constitute a sunlight tracking device 92 (3).

The azimuth angle adjusting device 90 includes known arbitrary mechanisms such as a driving geared motor and a worm gear reducer and a not-shown computer control means, and the rail 84 is reciprocally moved in an arrow direction 93 so that the upper surface (light receiving surface) 7h of the light converging-type solar photovoltaic apparatus 6h serves as a surface capable of receiving the sunlight efficiently.

The inclination angle (elevational angle) adjusting device 91 includes known arbitrary mechanisms such as a driving geared motor and a worm gear reducer and a not-shown computer control means and is inclined reciprocally in an arrow 93a direction so that the upper surface (light receiving surface) 7h of the light converging-type solar photovoltaic apparatus 6h can receive the sunlight efficiently.

The two or more opening portions may be provided at each of the opposing surfaces of the peripheral members of the cases. Further, as the need arises, the two or more opening portions at each of the opposed surfaces may be disposed at the upper portion close to the Fresnel lens side and the lower portion close to the solar battery cell side, respectively.

Like the case of FIG. 3, the opening portions 50h at the light converging-type power generation module 6ah exemplarily shown in FIG. 8B, FIG. 8C are provided at the opposing peripheral member 25h and peripheral member 26h as shown in FIG. 8B. Further, as the need arises, each of the opening portions 50h may be provided with a vent valve as described above.

According to the aforesaid configuration, as explained with reference to FIG. 3, natural wind is generated in an arrow 63h direction and so water collected in the grooves of the Fresnel lenses 45h can be removed in a short time as explained above.

While the present invention has been described in detail and with reference to specific embodiments thereof, it will be apparent to one skilled in the art that various changes and modifications can be made therein without departing from the spirit and scope thereof.

The present application is based on Japanese Patent Application No. 2006-170978 filed on Jun. 21, 2006, and the contents thereof are incorporated herein by reference.

What is claimed is:

1. A light converging-type solar photovoltaic apparatus comprising:
a case comprising: a bottom member; a peripheral member; and an upper member so as to form a space in the case, the case inclining so as to face the upper member to the sun;
a plurality of Fresnel lenses provided at the upper member, the Fresnel lenses converging sun light;
a plurality of solar battery cells provided in the case, the solar battery cells each receiving each sun light converged by the Fresnel lenses to generate electric power,
the peripheral member having surfaces opposed to each other, the opposed surfaces each having at least one opening portion, and
a vent valve provided at each opening portion, the vent valve comprising a mesh interrupting ventilation upon a water film being formed on the mesh.

2. The light converging-type solar photovoltaic apparatus according to claim 1,
wherein the opposed surfaces each have at least two opening portions, and one of the two opening portions is disposed at an upper portion close to the Fresnel lenses and the other is disposed at a lower portion close to the solar battery cells.

3. The light converging-type solar photovoltaic apparatus according to claim 2,
wherein the one of the two opening portions is disposed at a position where a distance between an upper end portion of the opening portion and a lower edge of the Fresnel lenses is 30 mm or less, and
the other is disposed at a position where a distance between a lower end portion of the opening portion and the bottom member of the case is 30 mm or less.

4. A light converging-type solar photovoltaic apparatus comprising:
a case comprising: a bottom member; a peripheral member; and an upper member so as to form a space in the case, the case inclining so as to face the upper member to the sun;
a plurality of Fresnel lenses provided at the upper member, the Fresnel lenses converging sun light;
a plurality of solar battery cells provided in the case, the solar battery cells each receiving each sun light converged by the Fresnel lenses to generate electric power,
the case further comprising a circulation fan for generating a soft wind so as to cause a turbulence in the case.

5. The light converging-type solar photovoltaic apparatus according to claim 2,
wherein a water flashing plate for preventing rain water from entering into the case is disposed at an upper position of the one of the two opening portions disposed at an upper portion close to the Fresnel lenses.
